(19) United States
(12) Patent Application Publication
(10) Pub. No.: US 2004/0125843 A1
(43) Pub. Date: Jul. 1, 2004

(54) Semiconductor laser device, manufacturing method thereof, and optical disk reproducing and recording unit

(75) Inventors: Hidenori Kawanishi, Oxford (GB); Kei Yamamoto, Nara-shi (JP); Shuichi Hirukawa, Nara-shi (JP)

Correspondence Address: MORRISON & FOERSTER LLP, 1650 TYSONS BOULEVARD, SUITE 300, MCLEAN, VA, 22102, US

(73) Assignee: Sharp Kabushiki Kaisha, Osaka (JP)

(21) Appl. No.: 10/695,415

(22) Filed: Oct. 29, 2003

(30) Foreign Application Priority Data
Oct. 30, 2002 (JP) P2002-315902

(51) Int. Cl. H01S 5/00

(52) U.S. Cl. 372/46; 372/45

(57) ABSTRACT

A semiconductor laser device has at least a first conductivity-type lower clad layers, a quantum well active layer, and a second conductivity-type upper clad layer, which are stacked on a first conductivity-type GaAs substrate. The quantum well active layer is composed of a barrier layer and a well layer which are alternately stacked and both made of an InGaAsP-based material. The quantum well active layer is grown while being doped with a second conductivity type of impurity so as for the semiconductor laser device to exhibits high reliability even at the time of high-power driving as well as long life.

### BACKGROUND OF THE INVENTION

The present invention relates to a semiconductor laser device and a manufacturing method thereof. The present invention also relates to an optical disk reproducing and recording unit.

Semiconductor laser devices have been used in optical communication units and optical recording units. In response to growing need for the semiconductor laser devices with higher speed and larger capacity in recent years, research and development are being conducted for improving various properties of the semiconductor laser devices.

Among others, semiconductor laser devices of a 780 nm band, which have been conventionally used in optical disk reproducing (recording) units such as CDs (Compact Disks) and CD-R/RWs (Compact Disks-Readable/Rewritable), are generally manufactured from AlGaAs-based materials. Since the need for the CD-R/RWs with high-speed writing is also increasing, the semiconductor laser devices with higher power are demanded to meet this need.

As a conventional AlGaAs-based semiconductor laser device, there is known one as shown in FIG. 12 (see Japanese Patent Laid-Open Publication HEI 11-274644 Paragraph 0053 and FIG. 1 for example). The semiconductor laser device is structured such that on an n-GaAs substrate 501, there are stacked, one after another, an n-GaAs buffer layer 502, an n-Al_{0.5}Ga_{0.5}As lower clad layer 503, an Al_{0.35}Ga_{0.65}As lower guide layer 504, a multiple quantum well active layer 505 composed of alternately disposed Al_{0.12}Ga_{0.88}As well layers (two layers with layer thickness of 80 Å,) and Al_{0.35}Ga_{0.65}As barrier layers (three layers with layer thickness of 50 Å), an Al_{0.35}Ga_{0.65}As upper guide layer 506, a p-Al_{0.35}Ga_{0.65}As first upper clad layer 507, and a p-GaAs etching stop layer 508, and on top of the etching stop layer 508, there is formed a mesa stripe-shaped p-Al_{0.5}Ga_{0.5}As second upper clad layer 509, further on which a cover-shaped p-GaAs cap layer 510 is formed. On the both sides of the second upper clad layer 509, there are stacked an n-Al_{0.7}Ga_{0.3}As first current blocking layer 511 and an n-GaAs second current blocking layer 512 so that the region other than the mesa stripe functions as a current narrowing portion. On top of the second current blocking layer 512, a p-GaAs planarization layer 513 is provided, and on the entire plane, there is laid a p-GaAs contact layer 514.

Inventors of the present invention made the semiconductor laser device to examine its properties. As a result, a threshold current was about 35 mA and a COD (Catastrophic Optical Damage) level was about 160 mW.

The semiconductor laser devices with use of AlGaAs-based materials as described above tend to suffer COD generated during high-power driving on an end face from which laser light is emitted due to the influence of an active Al. This poses disadvantages of insufficient reliability and short life.

### SUMMARY OF THE INVENTION

An object of the present invention is to provide a semiconductor laser device which exhibits high reliability even at the time of high-power driving and which has long life, and a manufacturing method thereof.

Another object of the present invention is to provide an optical disk reproducing and recording unit having such a semiconductor laser device.

COD on a laser light-emitting end face is considered to be generated on the basis of the following mechanism. On the end face of a resonator, aluminum (Al) is easily oxidized; thereby a surface level is formed. Carriers injected into an active layer are neutralized through the level. At that time, heat is discharged, so that temperature of the end face locally rises. This temperature rise reduces a band gap in the active layer in the vicinity of the end face. Carriers generated by absorption of laser light in the active layer in the vicinity of the end face are again neutralized through the surface level, which generates heat. It is considered that repeating such positive feedback finally leads to meltdown of the end face, resulting in halt of oscillation.

In order to solve the above drawback, the inventors of the present invention conducted research on high-power semiconductor laser devices made of InGaAsP-based materials that contain no Al (Al free materials) in an active region, and acquired a semiconductor laser device with a maximum optical output up to around 250 mW, however, sufficient reliability of which was not obtained. As a result of analyzing the semiconductor laser device, it was found out that Zn, which is a p-type impurity, diffused up into the active layer, and the concentration thereof reached 2×10¹⁷ cm⁻³. Also, the result of observing the cross section of the device by means of a transmission electron microscope (TEM) showed that a quantum well structure was partially disordered and that a phase boundary between a well layer and a barrier layer was obscure.

Based on a result of the above analysis, the present invention provides a semiconductor laser device comprising:

a first conductivity-type semiconductor substrate;

a first conductivity-type lower clad layer deposited on the first conductivity-type semiconductor substrate;

a quantum well active layer deposited on the first conductivity-type lower clad layer and composed of a barrier layer and a well layer alternately stacked; and

a second conductivity-type upper clad layer deposited on the quantum well active layer, wherein

the quantum well active layer is doped with a second conductivity type of impurity.

In the semiconductor laser device according to the present invention, the quantum well active layer is doped with a second conductivity type of impurity. Consequently, diffusion of impurities from the upper and lower clad layers or the like into the quantum well active layer is suppressed. As a result, disorder caused by diffusion of impurities into the quantum well active layer is decreased, which prevents damage on crystallinity of the quantum well active layer. Therefore, the semiconductor laser device is able to exhibit high reliability even during high-power driving and to have a long life.

The present invention specifically provides a semiconductor laser device having an oscillation wavelength larger than 760 nm and smaller than 800 nm, the semiconductor laser device comprising:

a first conductivity-type GaAs substrate;

a quantum well active layer deposited on the first conductivity-type GaAs substrate, and composed of a barrier layer and a well layer alternately stacked which are made of an InGaAsP based material;

a second conductivity-type upper clad layer deposited on the quantum well active layer, wherein

the quantum well active layer is doped with Zn as a second conductivity type of impurity.

It is noted that “InGaAsP-based material” refers to InₓGa₁₋ₓAs_{y}P_{1-y} (where 0<x<1, 0<y<1).

In the semiconductor laser device, the quantum well active layer is doped with Zn as a second conductivity type of impurity, which decreases disorder caused by diffusion of impurities from the upper and lower clad layers or the like into the quantum well active layer. For example, in the case where the upper clad layer is doped with Zn (having a relatively high diffusion rate) as an impurity, diffusion of Zn from the upper clad layer into the quantum well active layer is suppressed since the concentration of Zn in the quantum well active layer is moderately high. As a result, damage on crystallinity of the quantum well active layer is prevented. Therefore, the semiconductor laser device is able to exhibit high reliability even during high-power driving and to have a long life.

In one embodiment of the present invention, a concentration of Zn doped in the quantum well active layer is 2×10¹⁷ cm⁻³ or less. The concentration of Zn makes it possible to secure laser oscillation in the quantum well active layer. Moreover, the concentration of Zn makes it possible to decrease or almost eliminate diffusion of Zn into the quantum well active layer, so that the same effects as the above are implemented.

The present invention also provides a semiconductor laser device comprising:

a first conductivity-type semiconductor substrate;

a first conductivity-type lower clad layer deposited on the first conductivity-type semiconductor substrate;

a quantum well active layer deposited on the first conductivity-type lower clad layer, and composed of a barrier layer and a well layer alternately stacked; and

a second conductivity-type upper clad layer deposited on the quantum well active layer, wherein

the quantum well active layer is doped with a first conductivity type of impurity.

In the semiconductor laser device according to the present invention, the quantum well active layer is doped with the first conductivity type of impurity. Consequently, diffusion of impurities from the upper and lower clad layers or the like into the quantum well active layer is suppressed. As a result, disorder caused by diffusion of impurities into the quantum well active layer is decreased, which prevents damage on crystallinity of the quantum well active layer. Therefore, the semiconductor laser device is able to exhibit high reliability even during high-power driving and to have a long life.

The present invention specifically provides a semiconductor laser device having an oscillation wavelength larger than 760 nm and smaller than 800 nm, the semiconductor laser device comprising:

a first conductivity-type GaAs substrate;

a first conductivity-type lower clad layer deposited on the first conductivity-type GaAs substrate;

a quantum well active layer deposited on the first conductivity-type lower clad layer, and composed of a barrier layer and a well layer alternately stacked which are made of an InGaAsP-based material; and

a second conductivity-type upper clad layer deposited on the quantum well active layer, wherein

the quantum well active layer is doped with Si as a first conductivity type of impurity.

In the semiconductor laser device, the quantum well active layer is doped with Si as a first conductivity type of impurity, which decreases disorder caused by diffusion of impurities from the upper and lower clad layers or the like into the quantum well active layer. For example, in the case where the lower clad layer is doped with Si as an impurity, diffusion of Si from the lower clad layer into the quantum well active layer is suppressed since the concentration of Si in the quantum well active layer is moderately high. As a result, damage on crystallinity of the quantum well active layer is prevented. Therefore, the semiconductor laser device is able to exhibit high reliability even during high-power driving and to have a long life.

In one embodiment of the present invention, a concentration of Si doped in the quantum well active layer is 2×10¹⁷ cm⁻³ or less. The concentration of Si makes it possible to secure laser oscillation in the quantum well active layer. Moreover, the concentration of Si makes it possible to decrease or almost eliminate diffusion of Si into the quantum well active layer. Therefore, the same effects as the above are implemented.

A semiconductor laser device in one embodiment of the present invention further comprises a guide layer made of an AlGaAs-based material and interposed between the quantum well active layer and the upper clad layer and between the quantum well active layer and the lower clad layer.

It is noted that “AlGaAs-based material” refers to AlₓGa₁₋ₓAs (where 0<x<1)

In the semiconductor laser device, energy difference in a conduction band (ΔEc) and energy difference in a valence band (ΔEv) are generated between the well layer made of the InGaAsP-based material and the guide layers made of the AlGaAs-based material, so that overflow of carriers from the well layer is suppressed. This makes it possible to achieve high power.

It is noted that an uppermost layer and a lowermost layer, which constitute the quantum well active layer, are formed as the barrier layers, so that the well layer involving light-emitting recombination is free from direct contact with an AlGaAs-based material. This prevents damage on reliability of the semiconductor laser device.

In one embodiment of the present invention, a mixed crystal ratio of Al in the AlGaAs-based material that constitutes the guide layers is larger than 0.2. Consequently, energy difference in a conduction band (ΔEc) and energy difference in a valence band (ΔEv) are both generated in balance between the well layer made of the InGaAsP-based material and the guide layer made of the AlGaAs-based material. This makes it possible to more preferably suppress the overflow of carriers from the well layers. Therefore, high power is achieved more securely in the semiconductor laser device.

In one embodiment of the present invention, the well layer has a compressive strain. Therefore, the semiconductor laser device having an oscillation wavelength larger than 760 nm and smaller than 800 nm is able to exhibit high reliability even during high-power driving and to have a long life.

It is noted that quantity of “strain” is expressed as (a₁-a_{GaAs})/a_{GaAs} where a_{GaAs} is a lattice constant of the GaAs substrate, and a₁ is a lattice constant of the well layer. With a resultant value being positive, the strain is called a compressive strain, whereas with a resultant value being negative, it is called a tensile strain.

In one embodiment of the present invention, quantity of the compressive strain is 3.5% or less. Therefore, the semiconductor laser device exhibits higher reliability and longer life.

In one embodiment of the present invention, the barrier layer made of an InGaAsP-based material has a tensile strain. Thereby, the compressive strain of the well layer is compensated, so that the crystallinity of the quantum well active layer is more stabilized. Therefore, the semiconductor laser device having an oscillation wavelength larger than 760 nm and smaller than 800 nm is able to exhibit high reliability even during high-power driving and to have a long life.

In one embodiment of the present invention, quantity of the tensile strain is 3.5% or less. Therefore, the above effects are preferably obtained.

The present invention provides a manufacturing method of a semiconductor laser device, comprising:

depositing a first conductivity-type lower clad layer on a first conductivity-type semiconductor substrate;

depositing a quantum well active layer on the first conductivity-type lower clad layer, the quantum well active layer being composed of a barrier layer and a well layer alternately stacked; and

depositing a second conductivity-type upper clad layer on the quantum well active layer, wherein

the quantum well active layer is grown while being doped with a second conductivity type of impurity.

In the manufacturing method of the semiconductor laser device according to the present invention, the quantum well active layer is grown while being doped with the second conductivity type of impurity, so that diffusion of impurities from upper and lower clad layers or the like into the quantum well active layer is suppressed. As a result, disorder caused by diffusion of impurities into the quantum well active layer is decreased, which prevents damage on crystallinity of the quantum well active layer. Therefore, the manufactured semiconductor laser device is able to exhibit high reliability even during high-power driving and to have long life.

The present invention also provides a manufacturing method of a semiconductor laser device having an oscillation wavelength larger than 760 nm and smaller than 800 nm, the manufacturing method comprising:

depositing a first conductivity-type lower clad layer on a first conductivity-type GaAs substrate;

depositing a quantum well active layer on the first conductivity-type lower clad layer, the quantum well active layer being composed of a barrier layer and a well layer alternately stacked which are made of an InGaAsP based material; and

depositing a second conductivity-type upper clad layer on the quantum well active layer, wherein

the quantum well active layer is grown while being doped with Zn as a second conductivity type of impurity.

In this manufacturing method of the semiconductor laser device, the quantum well active layer is grown while being doped with Zn as a second conductivity type of impurity, which decreases disorder caused by diffusion of impurities from the upper and lower clad layers or the like into the quantum well active layer. For example, in the case where the upper clad layer is doped with Zn (having a relatively high diffusion rate) as an impurity, diffusion of Zn from the upper clad layer into the quantum well active layer is suppressed since the concentration of Zn in the quantum well active layer is moderately high. As a result, damage on crystallinity of the quantum well active layer is prevented. Therefore, the manufactured semiconductor laser device is able to exhibit high reliability even during high-power driving and to have long life.

In one embodiment of the present invention, Zn is so doped that a concentration thereof in the quantum well active layer is 2×10¹⁷ cm⁻³ or less. The concentration of Zn makes it possible to secure laser oscillation in the quantum well active layer. Moreover, the concentration of Zn makes it possible to decrease or almost eliminate diffusion of Zn into the quantum well active layer, so that the same effects as the above are implemented.

The present invention provides a manufacturing method of a semiconductor laser device, comprising:

depositing a first conductivity-type lower clad layer on a first conductivity-type semiconductor substrate;

depositing a quantum well active layer on the first conductivity-type lower clad layer, the quantum well active layer being composed of a barrier layer and a well layer alternately stacked; and

depositing a second conductivity-type upper clad layer on the quantum well active layer, wherein

the quantum well active layer is grown while being doped with a first conductivity type of impurity.

In the manufacturing method of the semiconductor laser device according to the present invention, the quantum well active layer is grown while being doped with the first conductivity type of impurity, so that diffusion of impurities from the upper and lower clad layers or the like into the quantum well active layer is suppressed. As a result, disorder caused by diffusion of impurities into the quantum well active layer is decreased, which prevents damage on crystallinity of the quantum well active layer. Therefore, the manufactured semiconductor laser device is able to exhibit high reliability even during high-power driving and to have long life.

The present invention specifically provides a manufacturing method of a semiconductor laser device having an oscillation wavelength larger than 760 nm and smaller than 800 nm, the manufacturing method comprising:

depositing a first conductivity-type lower clad layer on a first conductivity-type GaAs substrate;

depositing a quantum well active layer on the first conductivity-type lower clad layer, the quantum well active layer being composed of a barrier layer and a well layer alternately stacked which are made of an InGaAsP based material; and

depositing a second conductivity-type upper clad layer on the quantum well active layer, wherein

the quantum well active layer is grown while being doped with Si as a first conductivity type of impurity.

In the manufacturing method of the semiconductor laser device according to the present invention, the quantum well active layer is grown while being doped with Si as a first conductivity type of impurity, which decreases disorder caused by diffusion of impurities from the upper and lower clad layers or the like into the quantum well active layer. For example, in the case where the lower clad layer is doped with Si as an impurity, diffusion of Si from the lower clad layer into the quantum well active layer is suppressed since the concentration of Si in the quantum well active layer is moderately high. As a result, damage on crystallinity of the quantum well active layer is prevented. Therefore, the manufactured semiconductor laser device is able to exhibit high reliability even during high-power driving and to have long life.

In one embodiment of the present invention, Si is so doped that a concentration thereof in the quantum well active layer is 2×10¹⁷ cm⁻³ or less. Therefore, this concentration of Si makes it possible to secure laser oscillation in the quantum well active layer. Moreover, the concentration of Si makes it possible to decrease or almost eliminate diffusion of Si into the quantum well active layer, so that the same effects as the above are implemented.

The present invention also provides an optical disk reproducing and recording unit comprising the above-stated semiconductor laser device.

Optical disk reproducing and recording units are generally required to implement high-speed write operation by reducing the access time to optical disks during write operation. The optical disk reproducing and recording unit of the present invention, in which the above-stated semiconductor laser device is used, exhibits high reliability even during high-power driving and has long life as described above. More specifically, the semiconductor laser device operates with higher optical power than conventional. As a result, the optical disk reproducing and recording unit is able to enhance the rotational speed of the optical disk higher than conventional and thereby reduce the access time to optical disks. Therefore, data read-and-write operations, particularly the write operation, are implementable at higher speed than conventional. This provides users with more comfortable operability.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a cross sectional view showing a semiconductor laser device according to a first embodiment of the present invention, in which a cross sectional plane is vertical to a stripe direction (longitudinal direction of resonator);

FIG. 2 is a cross sectional view showing the semiconductor laser device according to the first embodiment of the present invention after termination of a first masking process for crystal growth, in which a cross sectional plane is vertical to the stripe direction;

FIG. 3 is a cross sectional view showing the semiconductor laser device according to the first embodiment of the present invention after termination of an etching process for forming a mesa stripe, in which a cross sectional plane is vertical to the stripe direction;

FIG. 4 is a cross sectional view showing the semiconductor laser device according to the first embodiment of the present invention after termination of a crystal growing process for embedding a current blocking layer, in which a cross sectional plane is vertical to the stripe direction;

FIG. 5 is a cross sectional view showing a semiconductor laser device according to a second embodiment of the present invention, in which a cross sectional plane is vertical to a stripe direction;

FIG. 6 is a graph view showing results of reliability tests of the semiconductor laser device according to the first and second embodiments of the present invention together with a result of a comparative example;

FIG. 7 is a graph view showing the difference in reliability of the semiconductor laser device of the present invention due to the difference in quantity of compressive strain in a well layer;

FIG. 8 is a graph view showing the relationship between a mixed crystal ratio of Al in a guide layer and a temperature characteristic in the semiconductor laser device of the present invention;

FIG. 9 is a graph view showing the relationship between the quantity of impurities doped in a quantum well active layer and a threshold current value;

FIG. 10 is a view showing impurities' concentration profiles generated by diffusion of impurities with the presence and the absence of impurities doped in the quantum well active layer;

FIG. 11 is a schematic view showing an optical disk reproducing and recording unit according to a third embodiment of the present invention; and

FIG. 12 is a cross sectional view showing a conventional semiconductor laser device, in which a cross sectional plane is vertical to a stripe direction.

### DETAILED DESCRIPTION OF THE PREFERRED EMBODIMENTS

Embodiments of the present invention will be described in detail hereinafter with reference to the drawings.

First Embodiment

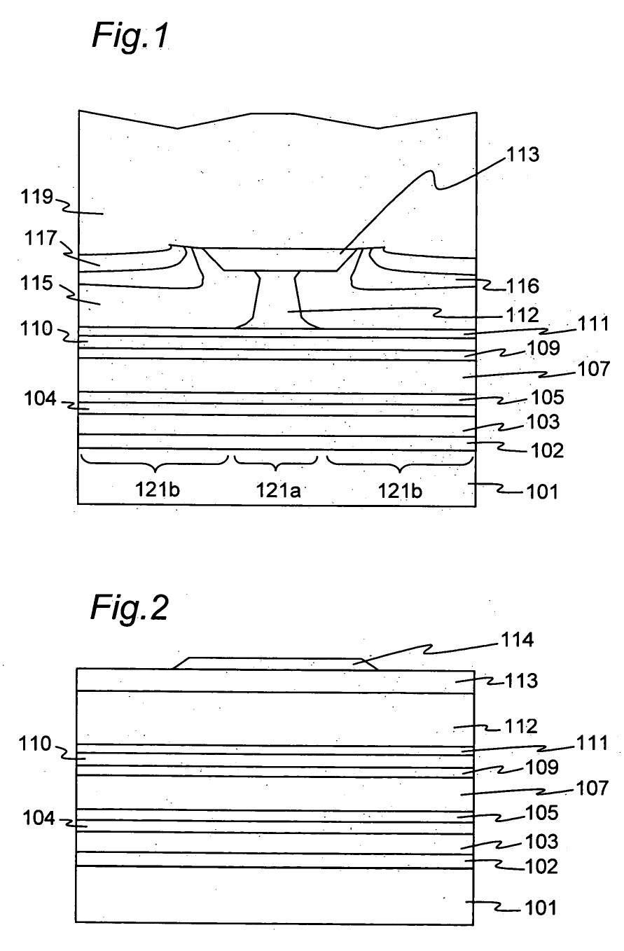

FIG. 1 shows the structure of a semiconductor laser device according to a first embodiment of the present invention. The semiconductor laser device is composed of an n-GaAs buffer layer 102, an n-Al_{0.466}Ga_{0.534}As first lower clad layer 103, an n-Al_{0.498}Ga_{0.502}As second lower clad layer 104, an Al_{0.433}Ga_{0.567}As lower guide layer 105, a strained multiple quantum well active layer 107, an Al_{0.433}Ga_{0.567}As upper guide layer 109, a p-Al_{0.4885}Ga_{0.5115}As first upper clad layer 110 and a p-GaAs etching stop layer 111 in the state of being stacked one after another on an n-GaAs substrate 101. On the etching stop layer 111, a mesa stripe-shaped p-Al_{0.4885}Ga_{0.5115}As second upper clad layer 112 and a GaAs cap layer 113 are provided, while the both sides of the mesa stripe-shaped p-Al_{0.4885}Ga_{0.5115}As second upper clad layer 112 and the GaAs cap layer 113 are filled with a light and current narrowing region made up of an n-Al_{0.7}Ga_{0.3}As first current blocking layer 115, an n-GaAs second current blocking layer 116 and a p-GaAs planarization layer 117. Further on the entire plane thereon, a p-GaAs cap layer 119 is provided.

It is noted that those with “n-” are layers doped with Si as an n-type impurity and those with “p-” are layers doped with Zn as a p-type impurity.

The strained multiple quantum well active layer 107 is composed of alternately disposed In_{0.932} Ga_{0.9068} As_{0.4071}P_{0.5929} barrier layers (three layers with strain of −1.44% and with layer thickness of 70 Å, 50 Å, 70 Å from the substrate side) and In_{0.2111}Ga_{0.7889}As_{0.6053}P_{0.3947} compressive-strained quantum well layers (two layers with strain of 0.12% and layer thickness of 80 Å). The quantity of strain is herein expressed as (a₁-a_{GaAs})/a_{GaAs} where a_{GaAs} is a lattice constant of the GaAs substrate, and a₁ is a lattice constant of the well layer. With a resultant value being positive, the strain is called a compressive strain, whereas with a resultant value being negative, it is called a tensile strain. In this embodiment, the quantum well active layer 107 is doped with Zn as a p-type impurity with a concentration of about 2×10¹⁷ cm⁻³.

The semiconductor laser device has a mesa stripe portion 121a and mesa stripe portion side portions 121b disposed on the both sides of the mesa stripe portion 121a. Though omitted in the drawing, electrodes are provided under the substrate 101 and on the cap layer 119, respectively, for operating the semiconductor laser device.

Next, with reference to FIGS. 2 to 4, description will be given of a manufacturing method of the semiconductor laser device.

As shown in FIG. 2, on an n-GaAs substrate 101 having (100) plane, there are formed through crystal growth by metal organic chemical vapor deposition process, one after another, an n-GaAS buffer layer 102 (layer thickness: 0.5 μm), an n-Al_{0.466}Ga_{0.534}As first lower clad layer 103 (layer thickness: 3.0 μm), an n-Al_{0.498}Ga_{0.502}As second lower clad layer 104 (layer thickness: 0.18 μm), an Al_{0.433}Ga_{0.567}As lower guide layer 105 (layer thickness: 70 nm), a strained multiple quantum well active layer 107, an Al_{0.433}Ga_{0.567}As upper guide layer 109 (layer thickness: 70 nm), a p-Al_{0.4885} Ga_{0.5115}As first upper clad layer 110 (layer thickness: 0.19 μm), a p-GaAs etching stop layer 111 (layer thickness: 30 Å), a p-Al_{0.4885}Ga_{0.5115}As second upper clad layer 112 (layer thickness: 1.28 μm) and a GaAs cap layer 113 (layer thickness: 0.75 μm).

In forming the quantum well active layer 107, the above-stated In_{0.0932}Ga_{0.9068}As_{0.4071}P_{0.5929} barrier layers (three layers with strain of −1.44% and with layer thickness of 70 Å, 50 Å, 70 Å from the substrate side) and In_{0.2111}Ga_{0.7889}As_{0.6053}P_{0.3947} compressive-strained quantum well layers (two layers with strain of 0.12% and layer thickness of 80 Å) are alternately crystal-grown while Zn as a p-type impurity is so doped as to obtain Zn concentration of 2×10¹⁷ cm⁻³

Further, on a portion where a mesa stripe portion is formed, a resist mask 114 (mask width: 5.5 μm) is so formed as to have a stripe along the (011) orientation by photographic process.

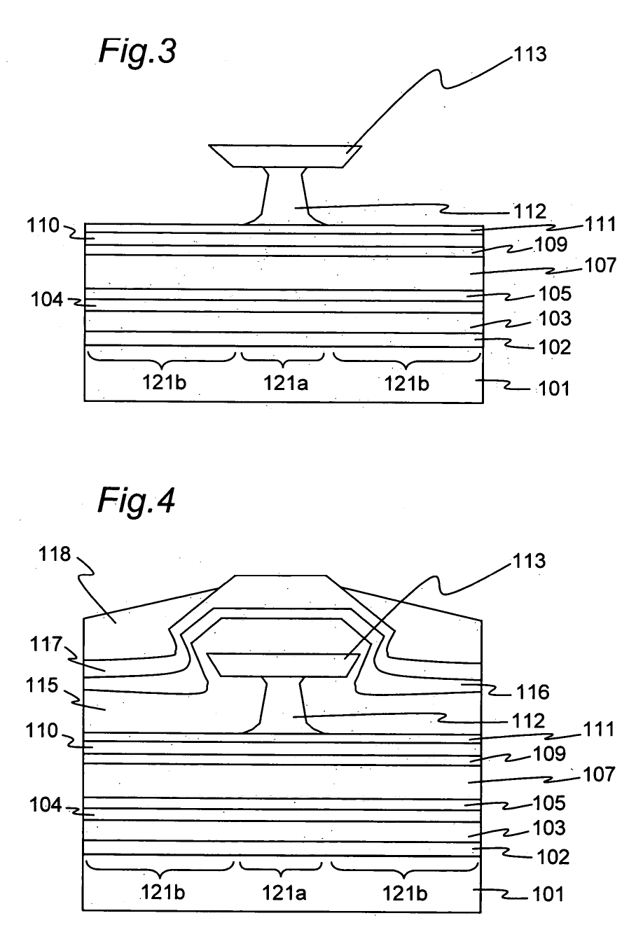

Next, as shown in FIG. 3, portions other than the resist mask 114 are removed by etching to form a mesa stripe portion 121a. The etching is carried out in two steps with use of mixed solution of sulfuric acid and hydrogen peroxide and hydrofluoric acid up to right above the etching stop layer 111. By utilizing the fact that an etching rate of GaAs by hydrofluoric acid is extremely low, planarization of the etching plane and width control of the mesa stripe are implemented. A depth of etching is 1.95 μm, and a width of the lowermost portion of the mesa stripe is about 2.5 μm. After the etching operation, the resist mask 114 is removed.

Next, as shown in FIG. 4, an n-Al_{0.7}Ga_{0.3}As first current blocking layer 115 (layer thickness: 1.0 μm), an n-GaAs second current blocking layer 116 (layer thickness: 0.3 μm) and a p-GaAs planarization layer 117 (layer thickness: 0.65 μm) are crystal-grown one after another by metal organic chemical vapor deposition process to form a light and current narrowing region.

Then, a resist mask 118 is formed only on the mesa stripe portion side portion 121b by photographic process. Next, the blocking layer on the mesa stripe portion 121a is removed by etching. The etching is carried out in two steps with use of mixed solution of ammonium and hydrogen peroxide and mixed solution of sulfuric acid and hydrogen peroxide. Then, the resist mask 118 is removed, and a p-GaAs cap layer 119 (layer thickness: 2.0 μm) is laid as shown in FIG. 1. Thus, a semiconductor laser device having a structure shown in FIG. 1 and having an oscillation wavelength of 780 nm may be manufactured.

FIG. 6 shows a result of reliability test of the semiconductor laser device of this embodiment conducted at 70° C. with use of a pulse of 230 mW, together with a result of a comparative example. In the drawing, reference numeral 6a denotes a result with respect to the semiconductor laser device of this embodiment, whereas reference numeral 6c denotes a result with respect to the comparative example (which is manufactured in totally the same way as the semiconductor laser device of this embodiment except that impurities are not doped in the quantum well active layer) (reference numeral 6b will be described later). As is clear from the drawing, the comparative example had characteristics deterioration in 2000 hours, whereas the semiconductor laser device of this embodiment stably operated for over 5000 hours. The inventors of the present invention had hitherto conducted research on semiconductor laser devices having an InGaAsP-based quantum well active layer on a GaAs substrate, and succeeded this time to manufacture a semiconductor laser device with a higher COD level than the AlGaAs-based semiconductor laser device. Moreover, for the purpose of increasing the life and reliability of the semiconductor laser device during high-power driving, the inventors doped impurities in the quantum well active layer, which fulfilled improvement of the characteristics of the semiconductor laser device. More specifically, as shown in this embodiment, it is considered that doping Zn, a p-type impurity, in the quantum well active layer and the upper guide layer to the extent of 2×10¹⁷ cm⁻³ enables diffusion of Zn coming from the upper clad layer to be suppressed, prevents the quantum well active layer 107 from being disordered, and prevents damage on the crystallinity, which leads to improvement of the characteristics of the semiconductor laser device. Diffusion of impurities in semiconductor layers is caused by gradient of the concentration of impurities among the semiconductor layers, so that decreasing the gradient, for example, as shown in FIG. 10 makes it possible to suppress the diffusion. It is noted that FIG. 10 shows impurities' concentration profiles along layer-stacking direction in the quantum well active layer 107, the upper guide layer 109 and the first upper clad layer 110, in which the gradient of impurities' concentration is smaller in the case where the quantum well active layer 107 is doped with impurities (expressed by a solid line 10a) than in the case where the quantum well active layer is not doped with impurities (expressed by a chain line 10b). It is further considered that a diffusion rate of impurities is higher in InGaAsP than in GaAs, so that doping impurities in advance in the quantum well active layer made of InGaAsP brings about particularly large effect of suppressing diffusion of impurities.

Further in this embodiment, Zn is used as a p-type impurity, which makes it possible to effectively suppress diffusion of impurities whose diffusion rate is high. Therefore, the manufactured semiconductor laser device is able to exhibit high reliability even during high-power driving and to have a long life.

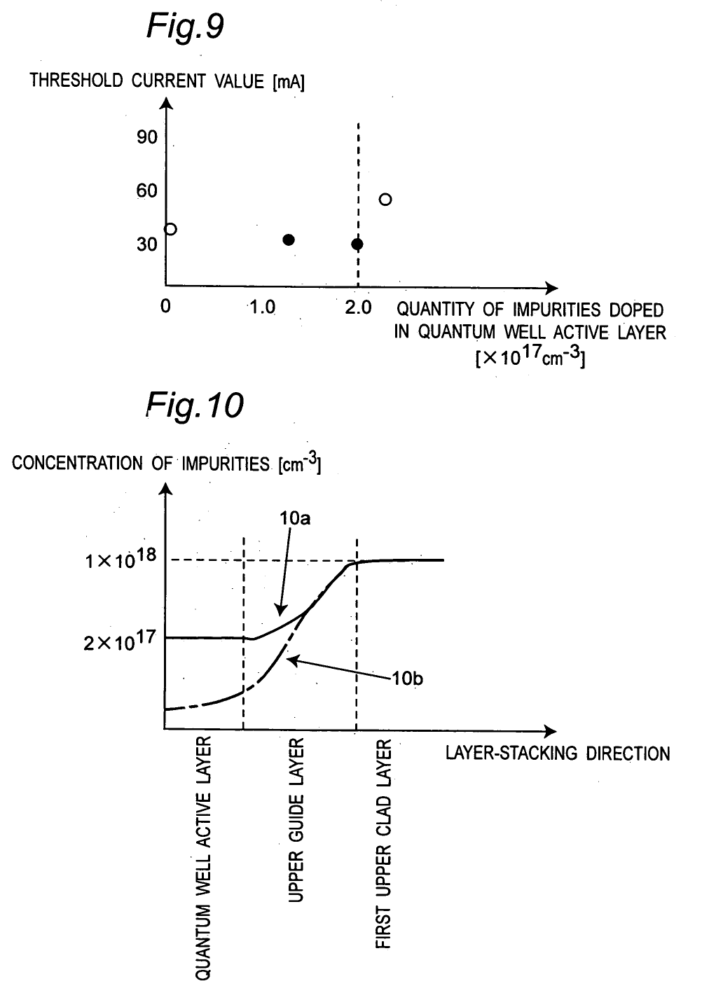

Further in this embodiment, the concentration of Zn doped in the quantum well active layer 107 is 2×10¹⁷ cm⁻³ or less, which makes it possible to decrease or almost eliminate diffusion of Zn into the quantum well active layer. Therefore, the manufactured semiconductor laser device is able to exhibit higher reliability during high-power driving and to have longer life. It is noted that with the concentration of Zn over 2×10¹⁷ cm⁻³, the quality of the quantum well active layer itself as InGaAsP was degraded as shown in FIG. 9, leading to deteriorated characteristics such as increased operating current values due to rise of a threshold value of laser oscillation.

Further in this embodiment, guide layers 109, 105 which are made of an AlGaAs-based material are interposed between the quantum well active layer 107 and the upper clad layer 110 and between the quantum well active layer 107 and the lower clad layer 104, respectively. Consequently, energy difference in a conduction band (ΔEc) and energy difference in a valence band (ΔEv) are generated between the well layer made of the InGaAsP-based material and the guide layers 109, 105 made of the AlGaAs-based material, so that overflow of carriers from the well layer is suppressed. This makes it possible to achieve high power. It is noted that an uppermost layer and a lowermost layer constituting the quantum well active layer are formed as the barrier layers, so that the well layer involving light-emitting recombination is free from direct contact with an AlGaAs-based material. This prevents damage on reliability of the semiconductor laser device.

In manufacturing an Al-free semiconductor laser device for achieving high reliability, generally, the layers up to the guide layer and the clad layers are all formed from Al-free materials such as InGaP. In this embodiment, however, AlGaAs whose mixed ratio of Al is larger than 0.2 is provided as a guide layer for obtaining, in good balance, energy difference in a conduction band (ΔEc) and energy difference in a valence band (ΔEv) against the well layer made of InGaAsP having an oscillation wavelength of 780 nm band. FIG. 8 is a graph view showing the relationship between a mixed crystal ratio of Al in the guide layer and a temperature characteristic (To). It was confirmed that the temperature characteristic was improved in the case where a mixed crystal ratio of Al in the guide layer made of AlGaAs was larger than 0.2, proving sufficiently high reliability.

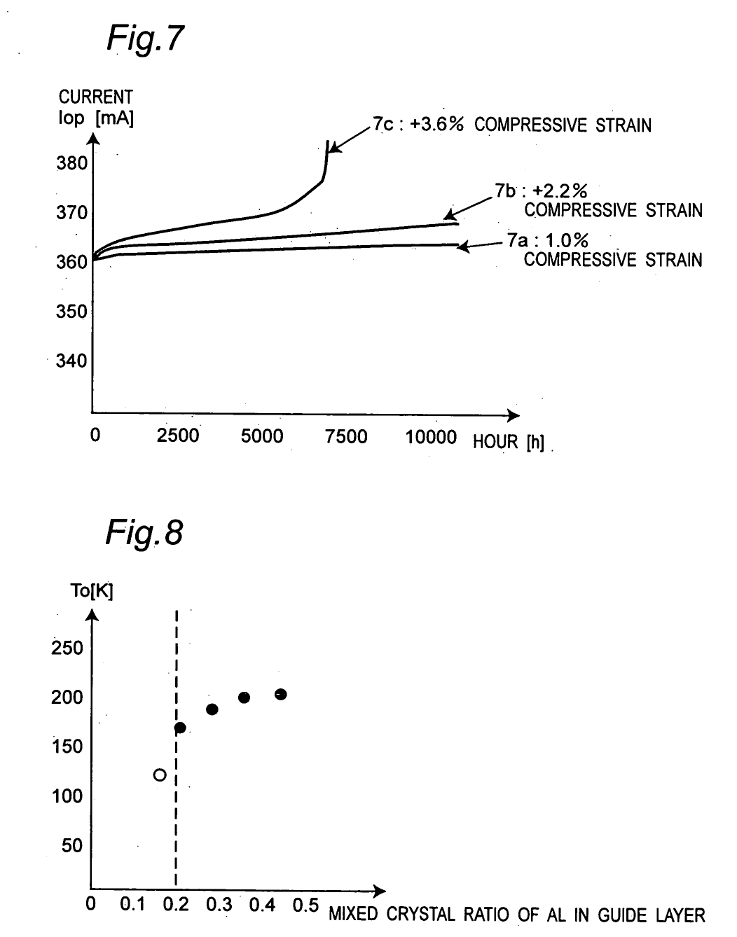

Also in this embodiment, the compressive-strained well layer made of InGaAsP is used on the GaAs substrate as described above. This fulfilled a semiconductor laser device having high reliability even during high-power driving particularly in a 780 nm band and having long life. Moreover, the above working effects were more preferably obtained with the quantity of strain being within 3.5%. More detailed description is given in FIG. 7, which shows the difference in reliability of the semiconductor laser device due to the difference in quantity of compressive strain in the well layer. In FIG. 7, reference numerals 7a, 7b, 7c respectively denote results of reliability tests conducted with the quantity of compressive strain in the well layer being +1.0%, +2.2%, 3.6% and with use of a 230 mW pulse at 70° C. According to the drawing, reliability is deteriorated when the quantity of compressive strain is over 3.5%. It is considered that crystallinity is deteriorated by excessively large quantity of compressive strain.

Also in this embodiment, quantity of strain in the well layer having a compressive strain was compensated by the tensile-strained barrier layer made of InGaAsP, which made it possible to manufacture a strained quantum well active layer with more stable crystal, resulting in a semiconductor laser device with high reliability. Further, with the quantity of tensile strain being 3.5% or less, the above working effects were obtained more preferably.

Second Embodiment

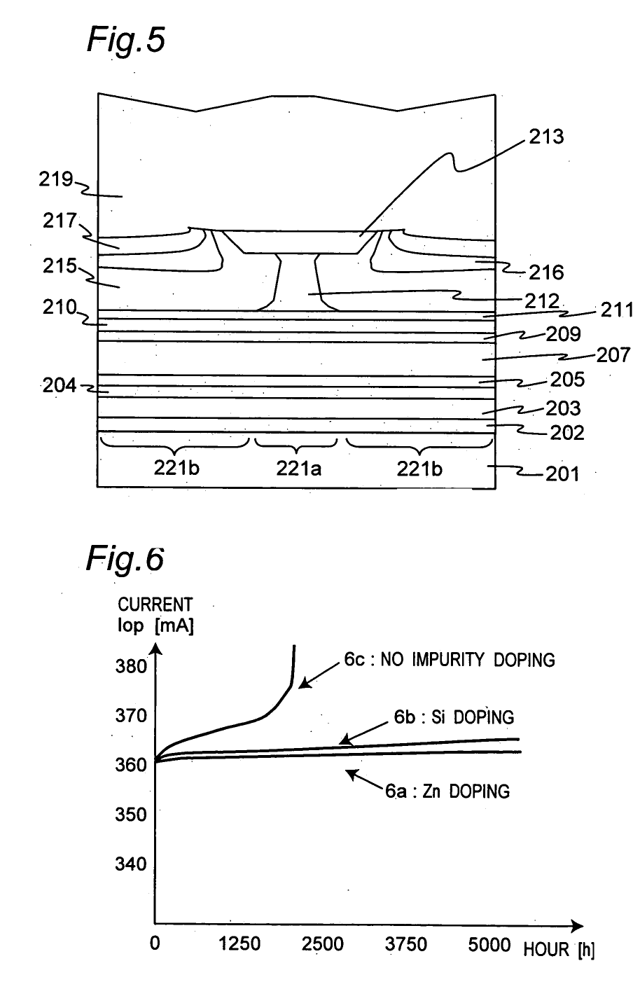

FIG. 5 shows the structure of a semiconductor laser device according to a second embodiment of the present invention.

The semiconductor laser device is composed of an n-GaAs buffer layer 202, an n-Al_{0.466}Ga_{0.534}As first lower clad layer 203, an n-Al_{0.498}Ga_{0.502}As second lower clad layer 204, an Al_{0.433}Ga_{0.567}As lower guide layer 205, a strained multiple quantum well active layer 207, an Al_{0.433}Ga_{0.567}As upper guide layer 209, a p-Al_{0.488}Ga_{0.5115}As first upper clad layer 210 and a p-GaAs etching stop layer 211 in the state of being stacked one after another on an n-GaAs substrate 201. On the etching stop layer 211, a mesa stripe-shaped p-Al_{0.4885}Ga_{0.5115}As second upper clad layer 212 and a GaAs cap layer 213 are provided, while the both sides of the mesa stripe-shaped p-Al_{0.4885}Ga_{0.5115}As second upper clad layer 212 and the GaAs cap layer 213 are filled with a light and current narrowing region made up of an n-Al_{0.7}Ga_{0.3}As first current blocking layer 215, an n-GaAs second current blocking layer 216 and a p-GaAs planarization layer 217. Further on the entire plane thereon, a p-GaAs cap layer 219 is provided.

The semiconductor laser device has a mesa stripe portion 221a and mesa stripe portion side portions 221b disposed on the both sides of the mesa stripe portion 221a. Though omitted in the drawing, electrodes are provided under the substrate 201 and on the cap layer 219, respectively, for operating the semiconductor laser device.

It is noted that, as with the first embodiment, those with “n-” are layers doped with Si as an impurity and those with “p-” are layers doped with Zn as an impurity. This embodiment is different from the first embodiment in the point that the quantum well active layer 207 itself is doped with Si as an n-type impurity with a concentration of about 2×10¹⁷ cm⁻³

The semiconductor laser device is manufactured from almost the same material to be almost the same layer thickness by almost the same manufacturing method as the first embodiment. However, in forming the quantum well active layer 207, the above-stated In_{0.0932}Ga_{0.9068}As_{0.4071}P_{0.5929} barrier layers (three layers with strain of −1.44% and with layer thickness of 70 Å, 50 Å, 70 Å from the substrate side) and In_{0.2111}Ga_{0.7889}As_{0.6053}P_{0.3947} compressive-strained quantum well layers (two layers with strain of 0.12% and layer thickness of 80 Å) are alternately crystal-grown while Si as an n-type impurity is so doped as to obtain Si concentration of 2×10¹⁷ cm⁻³. In other words, an uppermost layer and a lowermost layer of the quantum well active layer 207 are formed as barrier layers. This makes it possible to manufacture a semiconductor laser device having a structure shown in FIG. 5 and having an oscillation wavelength of 780 nm.

As shown by reference numeral 6b in FIG. 6, the semiconductor laser device in this embodiment operated stably for over 5000 hours in a reliability test conducted at 70° C. with use of a 230 mW pulse like the semiconductor laser device of the first embodiment.

Similarly in this embodiment, doping impurities in the quantum well active layer fulfilled improvement of the characteristics. Though detail is unclear, it is considered that doping Si, an n-type impurity, in the quantum well active layer 207, the upper guide layer 209, and the lower guide layer 205 to the extent of 2×10¹⁷ cm⁻³ enables diffusion of impurities into the quantum well active layer 207 to be suppressed, prevents the quantum well active layer from being disordered, and prevents damage on the crystallinity, which leads to improvement of the characteristics of the semiconductor laser device. It is further considered that a diffusion rate of impurities is higher in InGaAsP than in GaAs and the like, so that doping impurities in advance in the quantum well active layer made of InGaAsP as in this embodiment brings about particularly large effect of suppressing diffusion of impurities.

Further in this embodiment, Si is used as a p-type impurity, which makes it possible to effectively suppress diffusion of impurities whose diffusion rate is high. Therefore, the manufactured semiconductor laser device is able to exhibit high reliability even during high-power driving and to have long life.

Further in this embodiment, the concentration of Zn doped in the quantum well active layer 207 is 2×10¹⁷ cm⁻³ or less, which makes it possible to decrease or almost eliminate diffusion of impurities into the quantum well active layer. Therefore, the manufactured semiconductor laser device is able to exhibit higher reliability even during high-power driving and to have longer life. It is noted that with the concentration of Si over 2×¹⁷ cm³, the quality of the quantum well active layer itself as InGaAsP was degraded, leading to deteriorated characteristics such as increased operating current values due to rise of a threshold value of laser oscillation.

Further in this embodiment, guide layers 209, 205 which are made of an AlGaAs-based material are interposed between the quantum well active layer 207 and the upper clad layer 210 and between the quantum well active layer 207 and the lower clad layer 204, respectively. Consequently, energy difference in a conduction band (ΔEc) and energy difference in a valence band (ΔEv) are generated between the well layer made of the InGaAsP-based material and the guide layers 209, 205 made of the AlGaAs-based material, so that overflow of carriers from the well layer is suppressed like the first embodiment. This makes it possible to achieve high power. It is noted that an uppermost layer and a lowermost layer constituting the quantum well active layer are formed as the barrier layers, so that the well layer involving light-emitting recombination is free from direct contact with an AlGaAs-based material. This prevents damage on reliability of the semiconductor laser device.

Also in this embodiment, the compressive-strained well layer made of InGaAsP is used on the GaAs substrate 201 as described above. This fulfilled a semiconductor laser device having high reliability even during high-power driving particularly in a 780 nm band and having long life. Moreover, the above working effects were more preferably obtained with the quantity of strain being within 3.5%.

Also in this embodiment, quantity of strain in the well layer having a compressive strain was compensated by the tensile-strained barrier layer made of InGaAsP, which made it possible to manufacture a strained quantum well active layer with more stable crystal, resulting in a semiconductor laser device with high reliability. Further, with the quantity of tensile strain being 3.5% or less, the above working effects were obtained more preferably.

Furthermore, in the above-described first and second embodiments, a buried ridge structure is provided. However, this is not limitative and the same working effects can be obtained with any structure such as ridge structure, internal stripe structure and buried heterostructure.

Furthermore, although the n-type substrate has been used in the first and second embodiments, the same working effects can be obtained if a p-type substrate is used instead and the n-type and p-type of the individual layers are reversed.

Further, although a wavelength of 780 nm has been adopted, this is not limitative and the same working effects can be obtained only if the wavelength falls within a so-called 780 nm band which is larger than 760 nm and smaller than 800 nm.

Further, although the layer thickness of the p-GaAs cap layers 119, 219 has been set to 2 μm in the above-described first and second embodiments, the layers may be grown as thick as about 50 μm. Furthermore, although the growth temperature has been set to 750° C. and 680° C., this is not limitative.

Furthermore, although impurities are doped only in the quantum well active layers 107, 207 in the above-described first and second embodiments, impurities may be doped not only in the quantum well active layers but also in all the layers from the upper guide layer to the lower guide layers. Further, without being limited to Zn and Si, impurities may include C.

Third Embodiment

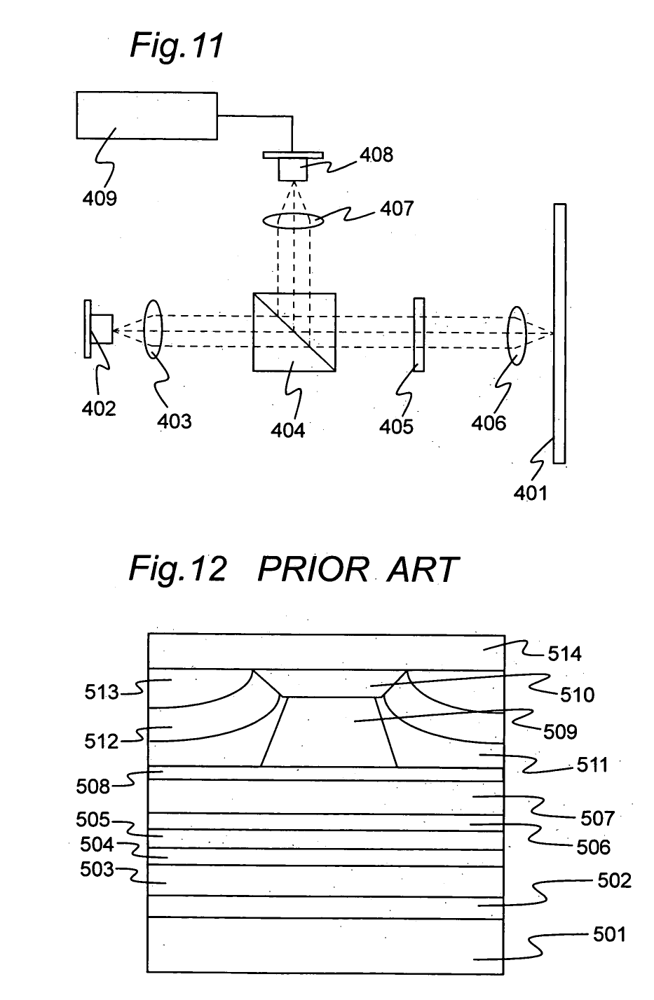

FIG. 11 shows an example of the structure of an optical disk reproducing and recording unit in the present invention. This optical disk reproducing and recording unit, which operates to write data on an optical disk 401 or reproduce data written on the optical disk 401, includes a semiconductor laser device 402 described in the first embodiment as a light-emitting device for use in those operations.

More detailed description of the optical disk reproducing and recording unit will be given below. For write operation, signal light emitted from the semiconductor laser device 402 becomes parallel light through a collimator lens 403, and is transmitted through a beam splitter 404. Then, after adjusted in polarization state by a λ/4 polarizer 405, the signal light is converged by an objective lens 406, irradiating the optical disk 401. For read operation, a laser beam with no data signal superimposed thereon travels along the same path as in the write operation, irradiating the optical disk 401. The laser beam reflected by the surface of the optical disk 401, on which data has been recorded, passes through the laser-beam irradiation objective lens 406 and the λ/4 polarizer 405, and is thereafter reflected by a beam splitter 404 so as to be changed in traveling direction by 90°. Subsequently, the laser beam is focused by a reproduction-light objective lens 407 and applied to a signal-detection use photodetector device 408. Then, in the signal-detection use photodetector device 408, a data signal recorded in response to the intensity of the incident laser beam is transformed into an electric signal, and reproduced to the original signal by a signal-light reproduction circuit 409.

The optical disk unit of this embodiment employs the semiconductor laser device 402 which operates with higher optical power than conventional, so that data read-and-write operations are implementable even if the rotational speed of the optical disk is enhanced higher than conventional. Accordingly, the access time to optical disks, which has hitherto mattered in write operations, can be reduced to a large extent, providing users with more comfortable operability.

This embodiment has been described on a case where the semiconductor laser device of the present invention is applied to a recording-and-reproduction type optical disk unit. However, this invention is not limited to this, and needless to say, applicable also to optical-disk recording units or optical-disk reproduction units using the same 780 nm wavelength band.

It should be understood that the semiconductor laser device and the optical disk reproducing and recording unit of the present invention are not limited to those described and illustrated above, and various modifications to, for example, the layer thickness of the well layer and the barrier layer and the number of the layers are acceptable without departing from the scope of the present invention.

As is clear from the forgoing description, the semiconductor laser device in the present invention exhibits high reliability even during high-power driving and has long life.

The optical disk reproducing and recording unit in the present invention includes such a semiconductor laser device, so that data read-and-write operations, particularly the write operation, are implementable at higher speed than conventional, providing users with more comfortable operability.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

What is claimed is:

1. A semiconductor laser device comprising:
a first conductivity-type semiconductor substrate;
a first conductivity-type lower clad layer deposited on the first conductivity-type semiconductor substrate;
a quantum well active layer deposited on the first conductivity-type lower clad layer and composed of a barrier layer and a well layer alternately stacked; and
a second conductivity-type upper clad layer deposited on the quantum well active layer, wherein
the quantum well active layer is doped with a second conductivity type of impurity.

2. A semiconductor laser device having an oscillation wavelength larger than 760 nm and smaller than 800 nm, the semiconductor laser device comprising:
a first conductivity-type GaAs substrate;
a quantum well active layer deposited on the first conductivity-type GaAs substrate, and composed of a barrier layer and a well layer alternately stacked which are made of an InGaAsP based material;
a second conductivity-type upper clad layer deposited on the quantum well active layer, wherein
the quantum well active layer is doped with Zn as a second conductivity type of impurity.

3. The semiconductor laser device as defined in claim 2, wherein
a concentration of Zn doped in the quantum well active layer is 2×10¹⁷ cm⁻³ or less.

4. The semiconductor laser device as defined in claim 2, further comprising:
a guide layer made of an AlGaAs-based material and interposed between the quantum well active layer and the upper clad layer and between the quantum well active layer and the lower clad layer.

5. The semiconductor laser device as defined in claim 4, wherein
a mixed crystal ratio of Al in the AlGaAs-based material that constitutes the guide layers is larger than 0.2.

6. The semiconductor laser device as defined in claim 2, wherein
the well layer has a compressive strain.

7. The semiconductor laser device as defined in claim 6, wherein
quantity of the compressive strain is 3.5% or less.

8. The semiconductor laser device as defined in claim 6, wherein
the barrier layer has a tensile strain.

9. The semiconductor laser device as defined in claim 8, wherein
quantity of the tensile strain is 3.5% or less.

10. An optical disk reproducing and recording unit comprising the semiconductor laser device as defined in claim 1.

11. A semiconductor laser device comprising:
a first conductivity-type semiconductor substrate;
a first conductivity-type lower clad layer deposited on the first conductivity-type semiconductor substrate;
a quantum well active layer deposited on the first conductivity-type lower clad layer, and composed of a barrier layer and a well layer alternately stacked; and
a second conductivity-type upper clad layer deposited on the quantum well active layer, wherein
the quantum well active layer is doped with a first conductivity type of impurity.

12. A semiconductor laser device having an oscillation wavelength larger than 760 nm and smaller than 800 nm, the semiconductor laser device comprising:
a first conductivity-type GaAs substrate;
a first conductivity-type lower clad layer deposited on the first conductivity-type GaAs substrate;
a quantum well active layer deposited on the first conductivity-type lower clad layer, and composed of a barrier layer and a well layer alternately stacked which are made of an InGaAsP-based material; and
a second conductivity-type upper clad layer deposited on the quantum well active layer, wherein
the quantum well active layer is doped with Si as a first conductivity type of impurity.

13. The semiconductor laser device as defined in claim 12, wherein
a concentration of Si doped in the quantum well active layer is 2×10¹⁷ cm⁻³ or less.

14. The semiconductor laser device as defined in claim 12, further comprising
a guide layer made of an AlGaAs-based material and interposed between the quantum well active layer and the upper clad layer and between the quantum well active layer and the lower clad layer.

15. The semiconductor laser device as defined in claim 14, wherein
a mixed crystal ratio of Al in the AlGaAs-based material that constitutes the guide layers is larger than 0.2.

16. The semiconductor laser device as defined in claim 12, wherein
the well layer has a compressive strain.

17. The semiconductor laser device as defined in claim 16, wherein
quantity of the compressive strain is 3.5% or less.

18. The semiconductor laser device as defined in claim 16, wherein
the barrier layer has a tensile strain.

19. The semiconductor laser device as defined in claim 18, wherein
quantity of the tensile strain is 3.5% or less.

20. An optical disk reproducing and recording unit comprising the semiconductor laser device as defined in claim 11.

21. A manufacturing method of a semiconductor laser device, comprising:
depositing a first conductivity-type lower clad layer on a first conductivity-type semiconductor substrate;
depositing a quantum well active layer on the first conductivity-type lower clad layer, the quantum well active layer being composed of a barrier layer and a well layer alternately stacked; and
depositing a second conductivity-type upper clad layer on the quantum well active layer, wherein
the quantum well active layer is grown while being doped with a second conductivity type of impurity.

22. A manufacturing method of a semiconductor laser device having an oscillation wavelength larger than 760 nm and smaller than 800 nm, the manufacturing method comprising:
depositing a first conductivity-type lower clad layer on a first conductivity-type GaAs substrate;
depositing a quantum well active layer on the first conductivity-type lower clad layer, the quantum well active layer being composed of a barrier layer and a well layer alternately stacked which are made of an InGaAsP-based material; and
depositing a second conductivity-type upper clad layer on the quantum well active layer, wherein
the quantum well active layer is grown while being doped with Zn as a second conductivity type of impurity.

23. The manufacturing method of the semiconductor laser device as defined in claim 22, wherein
Zn is so doped that a concentration thereof in the quantum well active layer is 2×10¹⁷ cm⁻³ or less.

24. A manufacturing method of a semiconductor laser device, comprising:
depositing a first conductivity-type lower clad layer on a first conductivity-type semiconductor substrate;
depositing a quantum well active layer on the first conductivity-type lower clad layer the quantum well active layer being composed of a barrier layer and a well layer alternately stacked; and
depositing a second conductivity-type upper clad layer on the quantum well active layer, wherein
the quantum well active layer is grown while being doped with a first conductivity type of impurity.

25. A manufacturing method of a semiconductor laser device having an oscillation wavelength larger than 760 nm and smaller than 800 nm, the manufacturing method comprising:
depositing a first conductivity-type lower clad layer on a first conductivity-type GaAs substrate;
depositing a quantum well active layer on the first conductivity-type lower clad layer, the quantum well active layer being composed of a barrier layer and a well layer alternately stacked which are made of an InGaAsP-based material; and
depositing a second conductivity-type upper clad layer on the quantum well active layer, wherein
the quantum well active layer is grown while being doped with Si as a first conductivity type of impurity.

26. The manufacturing method of the semiconductor laser device as defined in claim 25, wherein
Si is so doped that a concentration thereof in the quantum well active layer is 2×10¹⁷ cm⁻³ or less.
